(19) United States
(12) Patent Application Publication
(10) Pub. No.: US 2013/0260289 A1
(43) Pub. Date: Oct. 3, 2013

(54) METHOD OF MAKING A LITHOGRAPHY MASK

(71) Applicants: Yun-Yue Lin, Hsinchu City (TW); Hsin-Chang Lee, Hsin-Pu Zhen (TW); Chia-Jen Chen, Jhudong Township (TW); Ta-Cheng Lien, Cyonglin Township (TW); Anthony Yen, Zhubei City (TW)

(72) Inventors: Yun-Yue Lin, Hsinchu City (TW); Hsin-Chang Lee, Hsin-Pu Zhen (TW); Chia-Jen Chen, Jhudong Township (TW); Ta-Cheng Lien, Cyonglin Township (TW); Anthony Yen, Zhubei City (TW)

(73) Assignee: TAIWAN SEMICONDUCTOR MANUFACTURING COMPANY, LTD., Hsin-Chu (TW)

(21) Appl. No.: 13/437,565

(22) Filed: Apr. 2, 2012

(51) Int. Cl. G03F 1/78; B82Y 40/00

(52) U.S. Cl. 430/5; 977/901

(57) ABSTRACT

A method of fabricating a lithography mask with carbon-based-charging-dissipation (CBCD) layer is disclosed. The method includes providing a substrate, depositing an opaque layer on the substrate, coating a photoresist and depositing a charging dissipation layer on the photoresist. The photoresist is patterned by an electron-beam writing. The CBCD layer is removed during developing the photoresist.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, in an electron-beam lithography, a need of obtaining an adequate interlayer overlay raises challenges to efficiently dissipate accumulated charge. An accumulation of charge from the electron-beam on the photoresist deflects incoming electrons and causes pattern distortion. It is desired to have improvements in this area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a lithography system for implementing one or more embodiments of the present invention.

FIG. 2 is a flow chart of an example method for fabricating a lithography mask having charging dissipation layer constructed according to various aspects of the present disclosure.

FIGS. 3a and 3b illustrate cross sectional views of various aspects of one embodiment in various stages of fabricating a lithography mask constructed according to aspects of the present disclosure.

FIGS. 4a and 4b illustrate cross sectional views of various aspects of one another embodiment in various stages of fabricating a lithography mask constructed according to aspects of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

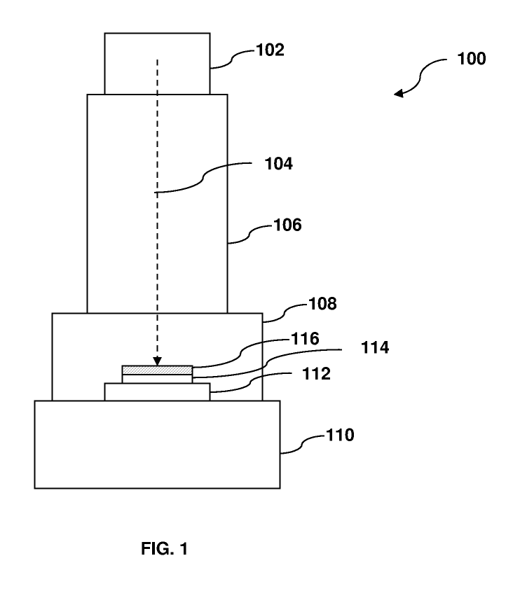

Referring to FIG. 1, an electron beam lithography system 100 includes an electron source 102, an electron beam 104, an electron optical column 106, a chamber 108, a pump unit 110, and a target stage 112. However, other configurations and inclusion or omission of devices may be possible. In the present disclosure, the electron beam lithography system 100 is also referred to as an electron beam writer or an electron beam writer system. The electron source 102 provides the electrons emitted from a conducting material by heating the conducting material to a very high temperature, where the electrons have sufficient energy to overcome the work function barrier and escape from the conducting material (thermionic sources), or by applying an electric field sufficiently strong that the electron tunnel through the barrier (field emission sources). The electron optical column 106 includes electromagnetic apertures, electrostatic lenses, electromagnetic lenses, and a shaping deflector and cell selection deflector. The electron optical column 106 provides a plurality of Gaussian spot electron beams, variable shaped electron beams and cell projection electron beams. The chamber 108 includes a target loading and unloading unit, and provides the target transportation without interrupting the vacuum of the system. The pump unit 110 includes one or more pumps and provides a high vacuum environment for the electron beam writer system. The target stage 112 includes motors, roller guides, and tables; and provides the accurate position and movement for a target 114, secured on the target stage 112 by vacuum, in X, Y and Z directions during focus, leveling and exposure process of the wafer in the electron beam lithography system.

The target 114 can be a lithography mask or a semiconductor wafer. In the present embodiment, the target 114 is a lithography mask (referred to as mask 114). In general, various masks are fabricated for being used in various processes. The mask 114 can be a transmissive mask or a reflective mask. A transmissive mask includes a transparent substrate and a patterned absorption (opaque) layer. A reflective mask includes a transparent substrate, a reflective multilayer (ML) and a patterned absorption layer. A light beam may be partially or completely blocked when directed on the opaque layer. The opaque layer may be patterned to have one or more openings through which a light beam may travel through (for a transmissive mask) or reflect from the reflective ML (for a reflective mask). The mask 114 may also incorporate other resolution enhancement techniques such as phase shift mask (PSM) and/or optical proximity correction (OPC).

The following description refers to the mask 114 and fabrication of the mask 114. In the present embodiment, the mask fabrication includes forming a blank mask and patterning the blank mask to form a patterned mask. The blank mask is formed by depositing suitable layers (e.g., multiple reflective layers) on a suitable substrate. The blank mask is patterned to carry out a design of an integrated circuit (IC) device (or chip). The patterned mask is used in a lithography process to transfer the circuit patterns onto the target (e.g., wafer). The pattern can be transferred over and over onto multiple wafers through various lithography processes. Several masks (for example, a set of 15 to 30 masks) may be used to construct a complete IC device.

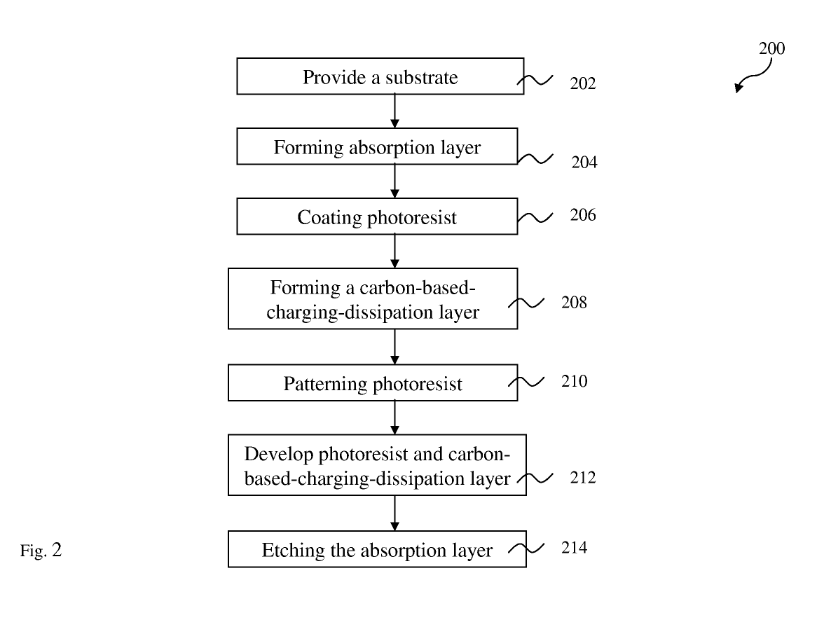

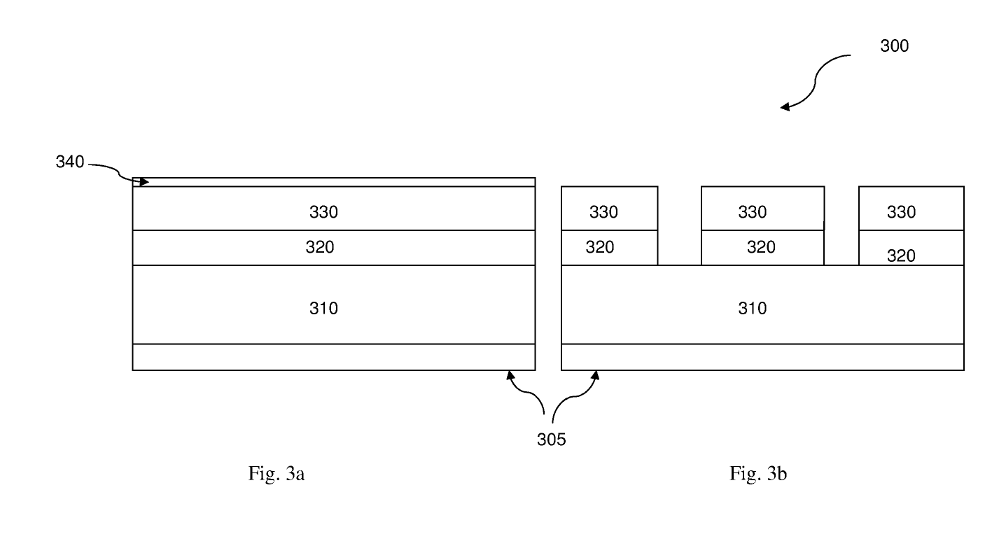

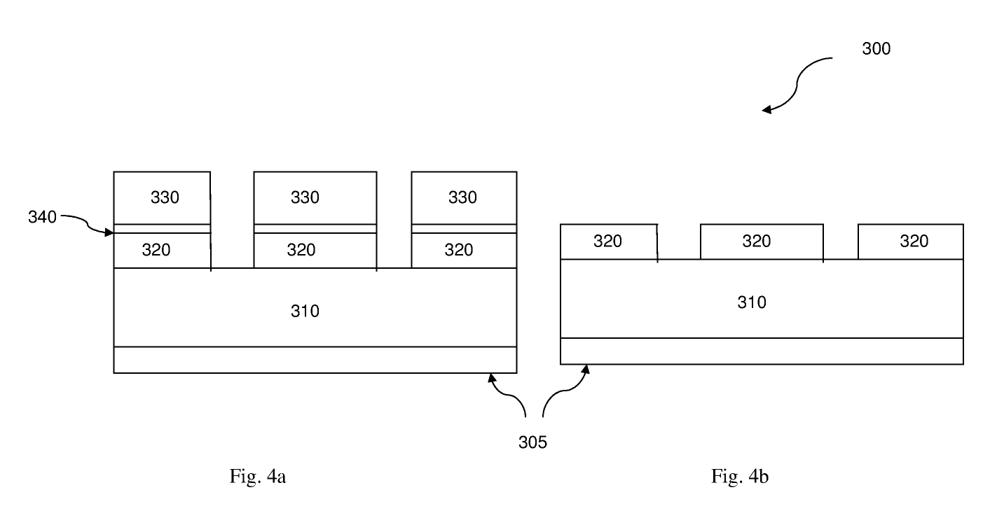

FIG. 2 is a flowchart of a method 200 of fabricating a mask 300 constructed according to aspects of the present disclosure. FIGS. 3a, 3b, 4a and 4b are sectional views of embodiment of the mask 300 at various fabrication stages of the method 200. The mask 300 and the method 200 of fabricating the same are collectively described with reference to FIGS. 2 through 4b.

The method 200 begins at step 202 by providing a substrate 310. The substrate 310 may include a low thermal expansion material (LTEM), such as TiO2, doped SiO2, and/or other low thermal expansion materials known in the art. In the present embodiment, the substrate 310 is a LETM substrate. The LTEM substrate 310 serves to minimize image distortion due to mask heating. The LTEM substrate 310 may also include materials with a low defect level and a smooth surface. In addition, a conductive layer 305 may be disposed under the LTEM substrate 310 to facilitate electrostatic chucking. In an embodiment, the conductive layer 305 includes chromium nitride (CrN), though other compositions are possible.

Alternatively, for fabricating a reflective mask, a reflective multilayer (ML, not shown) is deposited on the LTEM substrate 310. The reflective ML is configured by a large number of alternating layers of materials having a high refractive index and a low refractive index. Pairing these two types of materials together provides a resonant reflectivity. The reflective ML includes a plurality of film pairs, such as molybdenum-silicon (Mo/Si) film pairs (e.g., a layer of molybdenum above or below a layer of silicon in each film pair). A typical number of film pairs is 20-80, however any number of film pairs is possible. Additionally, a capping layer may be formed on top of the ML to prevent oxidation of the ML. Further additionally, a buffer layer may be formed on top of the capping layer to act as an etching stop layer in a patterning or repairing process of an absorption layer, which will be described later. The buffer layer has different etching characteristics from the absorption layer. The buffer layer includes ruthenium (Ru), Ru compounds such as RuB, RuSi, chromium (Cr), Cr oxide, and Cr nitride. A low temperature deposition process is often chosen for the buffer layer to prevent inter-diffusion of the ML. An example of a reflective ML is described in U.S. Ser. No. 13/328,166 which is hereby incorporated by reference.

The method 200 proceeds to step 204 by forming an absorption (an opaque) layer 320 on the LTEM substrate 310 (or on the ML for a reflective mask for some embodiments). The absorption layer 320 includes a single film layer or multiple film layers from a group of chromium, chromium oxide, titanium nitride, tantalum nitride, tantalum, titanium, or aluminum-copper, palladium, tantalum nitride, aluminum oxide, molybdenum (Mo), or other suitable materials. With a proper configuration, the absorption layer 320 will provide process flexibility in a subsequent etching process by different etch characteristics of each film. In present embodiment, the absorption layer 320 is a single chromium (Cr) layer.

Additionally, an antireflection (ARC) layer (not shown) may be deposited above the absorption layer 320. The ARC layer is configured to reduce a reflection of a lithographic radiation having a wavelength shorter than the deep ultraviolet (DUV) range from the absorption layer 320 for a DUV inspector. The ARC layer may use compound materials such as TaBO, Cr2O3, ITO, SiO2, SiN, TaO5, or any suitable material.

One or more of the layers 305, the ML, the capping layer, the buffer layer, the absorption layer 320 and the ARC layer may be formed by various methods, including physical vapor deposition (PVD) process such as evaporation and DC magnetron sputtering, a plating process such as electrode-less plating or electroplating, a chemical vapor deposition (CVD) process such as atmospheric pressure CVD (APCVD), low pressure CVD (LPCVD), plasma enhanced CVD (PECVD), or high density plasma CVD (HDP CVD), ion beam deposition, spin-on coating, metal-organic decomposition (MOD), atomic layer deposition (ALD), and/or other methods known in the art.

The method 200 proceeds to step 206 by depositing a photoresist 330 on the absorption layer 320. The photoresist 330 may be deposited by a spin-on process followed by a soft bake (SB) process. The photoresist 330 includes a positive tone resist or a negative tone resist. The photoresist 330 includes a single photoresist layer, or multiple photoresist layers.

The method 200 proceeds to step 208 by depositing a carbon-based-charging dissipation (CBCD) layer 340 on the photoresist 330, as shown in FIG. 3a. The CBCD layer 340 includes amorphous carbon, graphite, grapheme and any suitable isomer of carbon base materials with a mobility, μ, larger than 0.01 cm²/V.s. The CBCD layer 340 may be configured as a mono-layer molecular layer, a single layer, or multiple layers. The CBCD layer 340 has a thickness range from about 0.5 nm to about 50 nm. The CBCD layer 340 is formed by a suitable technique, such as CVD, PVD, ALD and MOD. The CBCD layer 340 provides a conductive layer with an adequate film adhesion and film stability with various photoresist types.

The method 200 proceeds to step 210 by patterning the photoresist 330 by an e-beam writing technique. For example, the photoresist 330 is patterned by the electron beams 104 in the electron beam lithography system 100 as shown in FIG. 1. During the e-beam writing process, accumulated charging in the photoresist 330 is dissipated by the CBCD layer 340.

The method 200 proceeds to step 212 by developing the photoresist 330. Electron beam exposure breaks the polymer in the photoresist 330 into fragments that are dissolved preferentially by a developing solution. The developing solution may remove the exposed or unexposed portions depending on the photoresist type. For a negative-type photoresist, the exposed portions are not dissolved by the developing solution and remain over the substrate. For a positive-type photoresist, the exposed portions would be dissolved by the a positive-tone developing solution, leaving the unexposed portions behind. With a negative-tone developing solution, the unexposed portions would be dissolved, leaving the exposed portions. The remaining exposed portions (or unexposed portions) define a pattern. During the developing process, the CBCD layer 340 may be dissolved and washed away completely by the developing solution. Alternatively, before the developing process, the CBCD layer 340 may be removed by a separate etching process, such as a wet etch. Various of existing photoresist developing processes are not only fairly easy to be adapted by the CBCD materials but also obtain a low defect advantage.

The method 200 proceeds to step 214 by etching the absorption layer 320 through the patterned photoresist layer 330, as shown in FIG. 3b. The absorption layer 320 may be etched by various methods, include a dry etch, a wet etch, or a combination of dry etch and wet etch. The dry etching process may use a fluorine-containing gas (e.g., CF4, SF6, CH2F2, CHF3, and/or C2F6), chlorine-containing gas (e.g., Cl2, CHCl3, CCl4, and/or BCl3), bromine-containing gas (e.g., HBr and/or CHBR3), oxygen-containing gas, iodine-containing gas, other suitable gases and/or plasmas, and/or combinations thereof. The etching process may include a multiple-step etching to gain etch selectivity, flexibility and desired etch profile.

In another embodiment, the CBCD layer 340 is disposed under the photoresist layer 330. During the developing process, a portion of the CBCD layer 340 under the dissolved photoresist portion is removed by the developing solution or by the subsequent absorption layer etching process, as shown in FIG. 4a. The rest of the CBCD layer 340 is removed during stripping the photoresist 330 process after etching, as shown in FIG. 4b.

The present disclosure provides many different embodiments of fabricating a lithography mask that provide one or more improvements over the prior art. In one embodiment, a method of fabricating a lithography mask includes providing a substrate, depositing an absorption layer on the substrate, coating photoresist on the absorption layer, forming a CBCD layer on the photoresist. The photoresist layer is patterned by an electron-beam lithography. After the photoresist is exposed to the electron-beam, the CBCD layer and the photoresist are developed to form a patterned photoresist. Then the absorption layer is etched through the patterned photoresist.

In another embodiment, a method of fabricating a lithography mask includes coating a conductive chromium nitride (CrN) layer at a first surface of a substrate, providing a reflective multilayer (ML) at a second, opposite surface of the substrate, forming an opaque layer on the ML, forming a photoresist layer on the opaque layer, forming a carbon-based-charging-dissipation (CBCD) layer on the photoresist layer. The photoresist layer is patterned by an electron-beam lithography. After the photoresist is exposed to the electron-beam, the CBCD layer and the photoresist are developed to form a patterned photoresist. Then the absorption layer is etched through the patterned photoresist.

In yet another embodiment, a method of fabricating lithography mask includes providing a substrate, forming an opaque layer on the substrate, forming a carbon-based-charging-dissipation (CBCD) layer on the opaque layer, forming a photoresist layer on the CBCD layer. The photoresist layer is patterned by an electron-beam lithography. After electron-beam exposure, the photoresist is developed and a portion of CBCD layer, which is under the dissolved photoresist portion, is washed away by the developing solution. The opaque layer is etched through the patterned photoresist to form patterned mask. After etching, the patterned photoresist and rest of the CBCD layer are removed.

Based on the above, it can be seen that the present disclosure offers a method of fabricating lithography mask with a CBCD layer to dissipate accumulative charging during a electron-beam writing process. The CBCD layer provides a charging dissipation layer with an adequate film adhesion with various types of photoresist. The CBCD materials offer convenience and low defect in both formation and subsequent removal processes. The CBCD materials demonstrate a feasible fabrication processes going along with photoresist fabrication processes. The method has demonstrated improvements of pattern placement errors, pattern distortions and overlay performance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a lithography mask comprising:
providing a substrate;
forming an opaque layer on the substrate;
forming a photoresist layer on the opaque layer;
forming a carbon-based-charging-dissipation (CBCD) layer adjacent the photoresist layer;
patterning the photoresist layer by an electron beam lithography;
removing the CBCD layer; and
etching the opaque layer.

2. The method of claim 1, wherein the CBCD layer includes a material selected from the group consisting of grapheme, graphite and amorphous carbon.

3. The method of claim 1, wherein the CBCD layer includes an isomer of carbon based material.

4. The method of claim 1, wherein the CBCD layer includes materials with a mobility larger than 0.01 cm²/V.s.

5. The method of claim 1, wherein the CBCD layer has a thickness from about 0.5 nm to about 50 nm.

6. The method of claim 1, wherein the CBCD layer includes a mono-layer molecular.

7. The method of claim 1, wherein the CBCD layer includes multiple layers.

8. The method of claim 1, wherein the CBCD layer is formed by atomic layer deposition (ALD) technique.

9. The method of claim 1, further comprising:
developing the photoresist layer, wherein the CBCD layer is removed during developing.

10. The method of claim 1, wherein the CBCD layer is removed by a wet etch before developing photoresist.

11. The method of claim 1, wherein the CBCD layer is disposed under the photoresist layer.

12. The method of claim 1, wherein the mask is a reflective mask.

13. The method of claim 12, wherein the substrate includes a reflective multilayer (ML) deposited on the substrate.

14. A method of fabricating a lithography mask comprising:
coating a conductive chromium nitride (CrN) layer at a first surface of a substrate;
providing a reflective multilayer (ML) at a second, opposite surface of the substrate;
forming an opaque layer on the ML;
forming a photoresist layer on the opaque layer;
forming a carbon-based-charging-dissipation (CBCD) layer on the photoresist layer;
performing electron-beam writing on the photoresist layer;
removing the CBCD layer; and
etching the opaque layer.

15. The method of claim 14, wherein the mask includes a transmissive mask.

16. The method of claim 14, wherein the CBCD layer includes one or more materials from a group comprising graphite, grapheme and amorphous carbon.

17. The method of claim 14, wherein the CBCD layer includes materials with a mobility larger than 0.01 cm²/V.s.

18. The method of claim 14, wherein a portion of the CBCD layer, which is under a dissolved photoresist portion, is removed by photoresist developing technique.

19. The method of claim 14, wherein a remain CBCD layer is removed by a photoresist stripping process.

20. A method of fabricating a lithography mask comprising:
providing a substrate;
forming an opaque layer on the substrate;
forming a carbon-based-charging-dissipation (CBCD) layer on the opaque layer;
forming a photoresist layer on the CBCD layer;
patterning the photoresist layer by a electron-beam lithography;
after electron-beam exposure, developing the photoresist, wherein a portion of CBCD is washed away by the developing solution;
etching the opaque layer to form patterned mask; and
after etching, removing the patterned photoresist and rest of the CBCD layer.
